(19) United States
(12) Patent Application Publication
(10) Pub. No.: US 2005/0169485 A1
(43) Pub. Date: Aug. 4, 2005

(54) Sound field control system and method

(75) Inventor: Yoshiki Ohta, Saitama (JP)

Correspondence Address: SUGHRUE MION, PLLC, 2100 PENNSYLVANIA AVENUE, N.W., SUITE 800, WASHINGTON, DC, 20037, US

(73) Assignee: PIONEER CORPORATION

(21) Appl. No.: 11/043,967

(22) Filed: Jan. 28, 2005

(30) Foreign Application Priority Data
Jan. 29, 2004 (JP) 2004-020959

(51) Int. Cl. H03G 3/00; G10H 1/02; G10H 7/00

(52) U.S. Cl. 381/63; 84/630

(57) ABSTRACT

In the sound field control system, the signal processing unit includes BPFs for dividing the sound signal into a plurality of frequency bands, and APFs for correcting the sound signal by adding a reflection sound pattern to the sound signal. APFs consist of the infinite impulse response type filter, with the delay amount and the gain being variable as coefficients. Once the sound field control processing is executed, the reverberation characteristic of the sound signal passing through BPFs and APFs is measured in the reproduction sound field, and compared with the reverberation characteristic of the original sound field measured in advance. As the result of the comparison, the coefficient showing a property most analogous to the reverberation characteristic of the original sound field is set to APFs in the zone.

### BACKGROUND OF THE INVENTION

1. Field of the Invention

The present invention relates to a sound field control system for and method of making a reverberation characteristic of a reproduction sound field analogous to an original sound field.

2. Description of the Related Art

The sound field control of this type is for realizing the target reverberation characteristic of the original sound field in the reproduction sound field where the audience listens to the sound. The applicant proposes a method using a finite impulse response type filter, referred to as a FIR (Finite Impulse Response) filter, in Japanese Patent Application Laid-Open No. 2003-255955.

According to this sound field control method, the reverberation characteristics of the original sound field and the reproduction sound field are firstly measured to obtain a difference therebetween. On the basis of the obtained difference, the FIR filter calculates a reflection sound pattern making the reverberation characteristic of the reproduction sound field analogous to the reverberation characteristic of the original sound field, and then adds that reflection sound pattern to the reproduction sound to be reproduced in the reproduction sound field. Therefore, it is considered that the reproduction sound field analogous to the original sound field can be realized.

### SUMMARY OF THE INVENTION

However, the conventional sound field control system has problems listed as below.

That is, in the method mentioned above, the FIR filter to generate the reflection sound pattern requires an enormous time period to identify the filter coefficient. Additionally in this case, there are so many parameters to control or adjust the property, as many as the number of filter coefficients. This makes it difficult to achieve the efficient and effective control or adjustment.

That is, in the conventional sound field control method, there is a technical problem of virtual impossibility in obtaining a desired reverberation characteristic quickly with less processing load.

The present invention has been achieved in view of above problems for example. It is therefore an object of the present invention to provide a sound field control system and sound field control method capable of shortening the processing time and reducing the processing load.

### Embodiment of Sound Field Control System

An embodiment of the sound field control system is a sound field control system for controlling a reverberation characteristic of a second sound field, on the basis of the measurement result of a reverberation characteristic of a first sound field in advance for a plurality of frequency bands, said sound field control system comprising: a frequency dividing device for dividing a sound signal into the plurality of frequency bands; a reverberation characteristic obtaining device for obtaining the reverberation characteristic of the second sound field for the plurality of frequency bands; a detecting device for detecting a difference between the reverberation characteristic of the second sound field and the reverberation characteristic of the first sound field, for the plurality of frequency bands; an infinite impulse response type filter for generating reflection sound information to be added to the sound signal divided into the plurality of frequency bands on the basis of the detected difference, for the plurality of frequency bands, and correcting the sound signal by adding the generated reflection sound information to the sound signal; and a synthesizing device for synthesizing the corrected sound signal for the plurality of frequency bands.

The “infinite impulse response type filter” herein is a filter in a form of IIR (Infinite Impulse Response), a filter which responds infinitely in theory to the input signal in a discrete time system.

According to the sound field control system, the infinite impulse response type filter generates reflection sound information to be added to the sound signal. Therefore, it is possible to shorten the processing time and reduce the processing load.

In an aspect of the embodiment of the sound field control system, the infinite impulse response type filter includes a first delay device with a variable delay amount and a gain device with a variable gain, and generates the reflection sound information on the basis of the delay amount and the gain.

According to this aspect, since the reflection sound information is generated on the basis of the delay amount of the first delay device and the gain of the gain device, it is possible to shorten the processing time and reduce the processing load.

In another aspect of the embodiment of the sound field control system including the first delay device and the gain device, the system further comprises: a coefficient holding device for holding a plurality of coefficient pairs in advance, each pair comprising the delay amount and the corresponding gain.

According to this aspect, a plurality of the variable delay amount and gain of the infinite impulse response type filter is held in advance as coefficient pairs. Therefore, it is possible to shorten the processing time required for generating the reflection sound information and reduce the processing load.

Furthermore, in another aspect of the embodiment of the sound field control system, the infinite impulse response type filter selects any one pair from among the coefficient pairs held by the coefficient holding device on the basis of the reverberation characteristic difference, and generates the reflection sound information on the basis of the delay amount and the gain corresponding to the selected coefficient pair.

According to this aspect, it is possible to generate the appropriate reflection sound information, since an appropriate pair is selected from among “pre-held” coefficient pairs and the reflection sound information is generated on the basis of the selected coefficient pair.

In another aspect of the embodiment of the sound field control system, the infinite impulse response type filter is an all pass type filter.

The “all pass type” herein means a concept that the frequency property of the filter is flat over the frequency band defining the reverberation characteristic of the original sound field or has another property near the former.

According to this aspect, since the infinite impulse response type filter is an all pass type filter, the difference of the filter pass property hardly likely arises among the divided frequency bands. Therefore, it is possible to obtain the good reverberation characteristic without the frequency distortion.

In another aspect of the embodiment of the sound field control system, the frequency dividing device divides the sound signal so that each of the divided frequency bands has a common zone with an adjacent zone.

According to this aspect, the sound signal is divided so that each of the divided frequency band has the common zone with the adjacent frequency band (zones). Therefore, it is possible to generate the acoustically natural reverberation sound.

In another aspect of the embodiment of the sound field control system, the reverberation obtaining device includes: a reference signal generating device for generating a reference signal; and a sound collecting device for collecting the reference signal outputted as a sound wave to the second sound field after through the frequency dividing device and the infinite impulse response type filter, in the second sound field, and obtains the reverberation characteristic of the second sound field on the basis of the collected reference signal.

According to this aspect, it is possible to collect the reference sound by the sound collecting device, the reference sound outputted into the second sound field after passing through the frequency dividing device and the infinite impulse response type filter. Strictly, it is possible to obtain the reverberation characteristic in the second sound field.

In another aspect of the embodiment of the sound field control system, the infinite impulse response type filter is made of a plurality of the infinite impulse response type filters, which are subsequently connected.

According to this aspect, since the infinite impulse response type filter is made of a plurality of infinite impulse response type filter sequentially connected, it is possible to generate the reflection sound information more in detail.

In another aspect of the embodiment of the sound field control system, the first delay device is the infinite impulse response type filter.

According to this aspect, since the first delay device as one constitutional element of the infinite impulse response type filter comprises the infinite impulse response type filter, it is possible to generate the reflection sound information more in detail.

Furthermore, in an aspect of the embodiment in which the first delay device comprises the infinite impulse response type filter, the infinite impulse response type filter includes: a second delay device having a fixed delay amount; and the infinite impulse response type filter.

According to this aspect, by means of the second delay device with the fixed delay amount, it is possible to provide easily the delay device with a variable delay amount.

### Embodiment of Sound Field Control Method

An embodiment of the sound field control method is a sound field control method of controlling a reverberation characteristic of a second sound field, on the basis of the measurement result of a reverberation characteristic of a first sound field in advance for a plurality of frequency bands, said sound field control method comprising: a frequency dividing process of dividing a sound signal into the plurality of frequency bands; a reverberation characteristic obtaining process of obtaining the reverberation characteristic of the second sound field for the plurality of frequency bands; a detecting process of detecting a difference between the reverberation characteristic of the second sound field and the reverberation characteristic of the first sound field, for the plurality of frequency bands; a sound signal correcting process of generating reflection sound information to be added to the sound signal divided into the plurality of frequency bands on the basis of the detected difference, and correcting the sound signal by adding the generated reflection sound information to the sound signal, by an infinite impulse response type filter; and a synthesizing process of synthesizing the corrected sound signal for the plurality of frequency bands.

According to this sound field control method, by means of the infinite impulse response type filter, the reflection sound information to be added to the sound signal is promptly generated. Therefore, it is possible to shorten the processing time and reduce the processing load.

In an aspect of the embodiment of the sound field control method, the infinite impulse response type filter includes a delay device with a variable delay amount and a gain device with a variable gain, and the sound signal correcting process includes a process of determining the delay amount and the gain on the basis of the detected reverberation difference.

According to this aspect, since determining the delay amount and gain makes it possible to generate the reflection sound information, it is possible to shorten the processing time and reduce the processing load.

In another aspect of the embodiment of the sound field control method, the gain is determined after the delay amount is determined at the sound signal correcting process.

According to this aspect, since the delay amount is firstly determined, it is possible to shorten the time required for generating the reflection sound information.

In another aspect of the embodiment of the sound field control method, the delay amount is adjusted to be different at least partially for the plurality of frequency bands, at the sound signal correcting process.

According to this aspect, since the delay amount of the delay device is prevented from being equal overall the divided frequency bands, it is possible to generate the acoustically natural reverberation sound.

In another aspect of the embodiment of the sound field control method, the reverberation characteristic obtaining process includes: a process of outputting a reference signal as a sound wave by an outputting device in the second sound field; and a process of collecting the outputted reference signal by a sound collecting device, the reverberation characteristic is obtained on the basis of the collected reference signal.

In an aspect of the embodiment in which the reverberation characteristic is obtained on the basis of the collected reference signal, the reference signal is an impulse signal, the reverberation characteristic is obtained on the basis of an impulse response between the outputting device and the sound collecting device.

According to this aspect, it is easy to obtain the reverberation characteristic.

In another aspect of the embodiment of the sound field control method in which the reverberation characteristic is obtained on the basis of the impulse response, the reverberation characteristic obtaining process includes a process of obtaining the reverberation characteristic through a simulation based on the impulse response.

According to this aspect, since a part of the reverberation characteristic can be obtained through the simulation based on the impulse response, it is possible to shorten remarkably the time required for obtaining the reverberation characteristic.

In another aspect of the embodiment of the sound field control method in which the reverberation characteristic is obtained on the collected reference signal, the reference signal is a random noise signal, the reverberation characteristic is obtained on the basis of the random noise collected over a plurality of times.

According to this aspect, the reverberation characteristic can be obtained from the random noise, it is easy to obtain the reverberation characteristic.

As discussed or explained above, according to the sound field control system, since there are provided with the frequency dividing device, the reverberation characteristic device, the detecting device, the infinite impulse response type filter and the synthesizing device, it is possible to shorten the processing time and reduce the processing load. According to the sound field control method, since there are provided with the frequency dividing process, the reverberation characteristic obtaining process, the detecting process, the sound signal correcting process and the synthesizing process, it is possible to shorten the processing time and reduce the processing load.

The nature, utility, and further features of this invention will be more clearly apparent from the following detailed description with reference to preferred embodiments of the invention when read in conjunction with the accompanying drawings briefly described below.

### BRIEF DESCRIPTION OF THE DRAWINGS

FIG. 1 is a block diagram of a first embodiment of the sound field control system according to the present invention.

FIG. 2 is a block diagram of APFs in the sound field control system.

FIG. 3 is a view showing an exemplary operation of APFs.

FIG. 4 is a flow chart of a sound field control processing executed by a CPU in the sound field control system 100.

FIG. 5 is a flow chart of a coefficient calculation processing in FIG. 4.

FIG. 6 is a schematic view of a coefficient table used in the coefficient calculation processing.

FIG. 7 is a block diagram of APFs in a second embodiment of the present invention.

FIG. 8 is a block diagram of APFs in a third embodiment of the present invention.

### DETAILED DESCRIPTION OF THE PREFERRED EMBODIMENTS

### Embodiments

Now, an explanation is made on an embodiment of the present invention, with reference to attached drawings.

### First Embodiment

### Construction of Embodiment

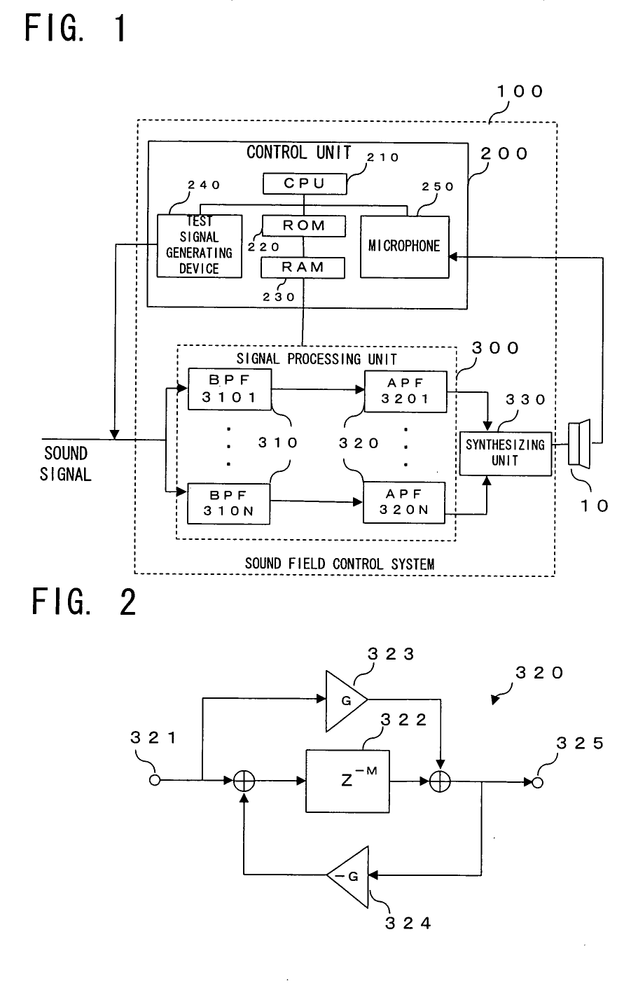

Firstly, with reference to FIG. 1, a construction of the first embodiment of the sound field control system according to the present invention will be discussed. FIG. 1 illustrates the sound field control system 100 in a block diagram.

In FIG. 1, the sound field control system 100 is provided with: a control unit 200; a signal processing unit 300; and a synthesizing unit 330. A sound signal supplied from the precedent process is processed by the control unit 200 and the signal processing unit 300, and outputted to a speaker 10 in the following process as an example of the “outputting device” according to the present invention.

The control unit 200 includes a CPU (Central Processing Unit) 210, a ROM (Read Only Memory) 220, a RAM (Random Access Memory) 230, a test signal generator 240 and a microphone 250.

The CPU 210 may act as the “finite impulse response type filter”, “reverberation characteristic obtaining device” and “detecting device” according to the present invention, or may be adapted to perform the “reverberation characteristic obtaining process”, “detecting process” and “sound signal correcting process” according to the present invention. The CPU 210 controls constitutional elements in the control unit 200 and the signal processing unit 300 so as to perform a sound field control processing, as discussed below.

In the ROM 220, the target reverberation characteristic R0 (R0=[R00, R01, . . . R0n]) of the original sound field (i.e. “the first sound field” according to the present invention) is recorded, the target reverberation characteristic R0 being divided into N frequency bands to be measured. Also in the ROM 220, a coefficient table as mentioned below is recorded. This acts as the “holding device” according to the present invention. In the RAM 230, coefficients of an APF 320, which is discussed below, is temporarily recorded in the sound field control processing. Additionally, the RAM 230 acts as a working area of the CPU 210. The test signal generator 240 is an example of the “reference signal generating device” according to the present invention, and the microphone 250 is an example of the “sound collecting device” according to the present invention. The test signal generator 240 and the microphone 250 each are used to measure the reverberation characteristic of the reproduction sound field (i.e. “the second sound field” according to the present invention) in the sound field control system.

The signal processing unit 300 includes BPFs 310 and APFs 320. The BPF 310 is an abbreviation of Band Pass Filter, acting as an example of the “frequency dividing device” according to the present invention. BPFs 310 includes N pieces of filters, BPF 3101, BPF 3102, . . . , BPF 310N, each having a different filter coefficient and a different frequency band to pass sound signal. Frequency bands of N quantities divided by the BPF 310 equal to frequency bands of the reverberation characteristic of the original sound field.

Incidentally, in this embodiment, the filter coefficients of the BPFs 310 are determined so that each zone partially overlaps the adjacent frequency bands at their both ends.

The APF 320 are made of APF 3201, APF 3202, . . . , APF 320N, total N piece IIR type All Pass Filters, and acts, in cooperation with the CPU 210, as the “infinite impulse response type filter” according to the present invention. APFs 320 are connected to tails of BPFs 310 respectively, for generating reflection sound pattern (i.e. the “reflection sound information” according to the present invention) to be added to the sound signal for each divided frequency band by BPF 310, and correcting the sound signal by adding the reflection sound pattern to the sound signal.

Now, with reference to FIG. 2, a detail of APFs 320 will be discussed. FIG. 2 illustrates an APF 320 in a block diagram.

In FIG. 2, an APF 320 is provided with an input terminal 321, a delay circuit 322, a first gain device 323, a second gain device 324 and an output terminal 325.

A sound signal divided into each zone is inputted to the input terminal 321 from a BPF 310, the precedent process of the APF 320.

The delay circuit 322 is a delay circuit having a delay amount “M”, which is an all pass parameter to define a time period for adding the reflection sound for every frequency band, and serves an example of the “delay device” according to the present invention. The delay circuit 322 delays the input signal inputted into the input terminal 321 for M sample minutes and then outputs the delayed signal to the output terminal 325. The first gain device 323 is a gain device having a gain “G”, and gives the gain “G” to the input signal, and outputs the input signal to the output terminal 325 without an intermediate of the delay circuit 322. The second gain device 324 is a gain device having a gain “−G”, and gives the gain “−G” to the output signal appearing at the output terminal 325, and feedbacks the signal to the delay circuit 322. Incidentally, the first gain device 323 and the second gain device 324 are as an example of the “gain device” according to the present invention. In the APF 320, the delay amount “M” and gain “G” are variable.

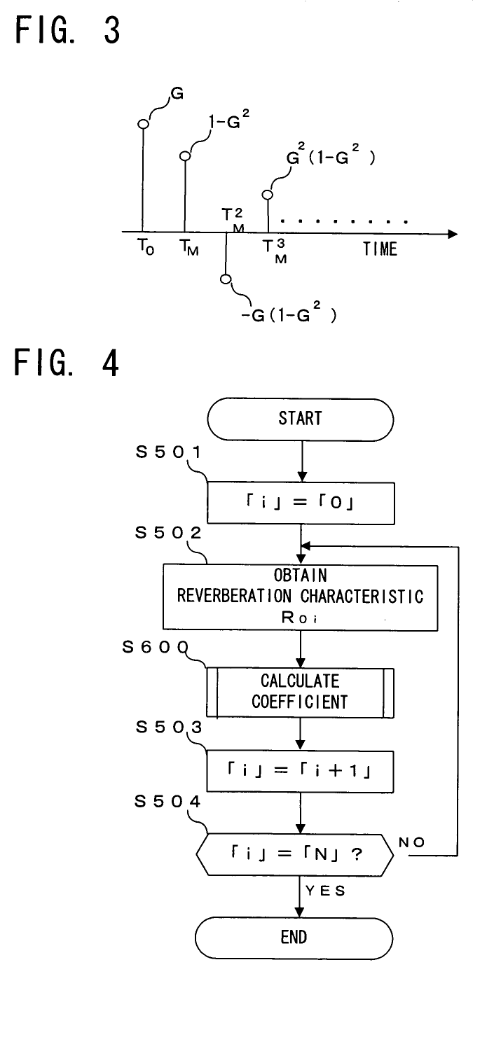

Now, an explanation is made on an operation of the APF 320, with reference to FIG. 3. FIG. 3 illustrates an example of the output signal of the APF 320.

In FIG. 3, a unit signal “1” is given as the input signal. In this case, the signal first appeared at the output terminal 325 is the signal passed through the first gain device 323. That is, the signal “G” is outputted at time TO. Then, this signal “G” is inputted to the delay circuit 322, after gained the gain “−G” by the second gain device 324. Therefore, the signal “(1−G²)” appears at the output terminal 325 at time T_{M}, i.e. a time delayed from T0 by M sample minutes. After then, the feedback is repeated through the second gain device 324, and the signal “−G(1−G²)” appears at time T_{2M}, the signal 13 “G²(1−G²)” appears at time T_{3M}. Thus, the signal once inputted to the APF 320 is damped gradually with the M sample minutes delay, and keep appearing for infinite time period at the output terminal 325.

Furthermore, as shown in FIG. 3, the APF 320 is made of only elements whose frequency passing property is flat, such as the delay circuit 322, the first gain device 323, and the second gain device 324. Therefore, the APF 320 is an all pass type filter capable of maintaining the frequency property of the input signal.

Referring to FIG. 1 again, the synthesizing unit 330, which is an example of the “synthesizing device” according to the present invention, is a circuit for synthesizing the sound signal corrected at the signal processing unit 300 comprising the BPFs 310 and APFs 320 for all frequency bands. The corrected sound signals synthesized at the synthesizing unit 330 are finally outputted from the speaker 10 as the sound signal having the reverberation characteristic analogous to the reverberation characteristic of the original sound field.

(Exemplary Operation)

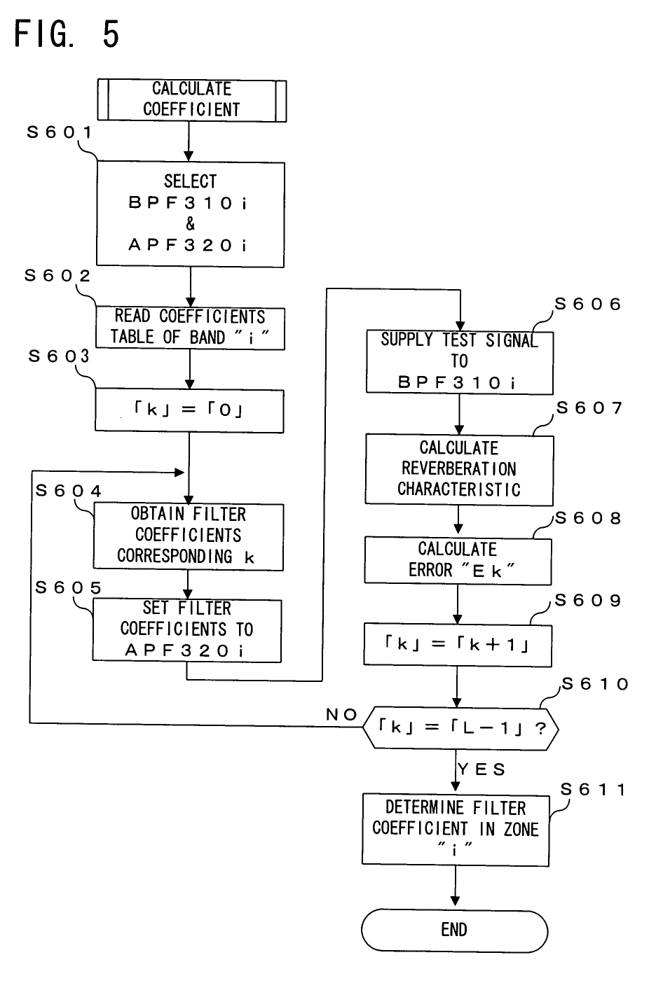

Now, an explanation is made on the operation of the sound field control system 100, i.e. an embodiment of the sound field controlling method according to the present invention, with reference to FIG. 4 and FIG. 5. FIG. 4 illustrates an operational flow of the sound control processing executed by the CPU 210. FIG. 5 illustrates an operational flow of the coefficient calculation processing of APFs 320. The “sound field control processing” herein is a processing to realize the reverberation characteristic analogous to the reverberation characteristic of the original sound field in the reproduction sound field, on the basis of the reverberation characteristic of the original sound field.

In FIG. 4, firstly the CPU 210 resets the counter “i” to “0” (step S501). Then, the CPU 210 reads the reverberation characteristic R0i of the original sound field corresponding to the frequency band “i” designated by the counter value “i” from the ROM 220, and stores it into the RAM 230 (step S502). Then, the CPU 210 performs the coefficient calculation processing to calculate the coefficients of APFs 320 corresponding to the frequency band “i”. The coefficients of APFs 320 are the delay amount “M” and the gain “G”, which are determined through the coefficient calculation processing.

In FIG. 5, once the coefficient calculation processing starts, the CPU 210 firstly selects a BPF 310 corresponding to the frequency band “i”, i.e. the BPF 310i, and an APF 320 corresponding to the frequency band “i”, i.e. the APF 320i (step S601). Then, the CPU 210 reads the coefficient table corresponding to the frequency band “i” from the ROM 220 (step S602).

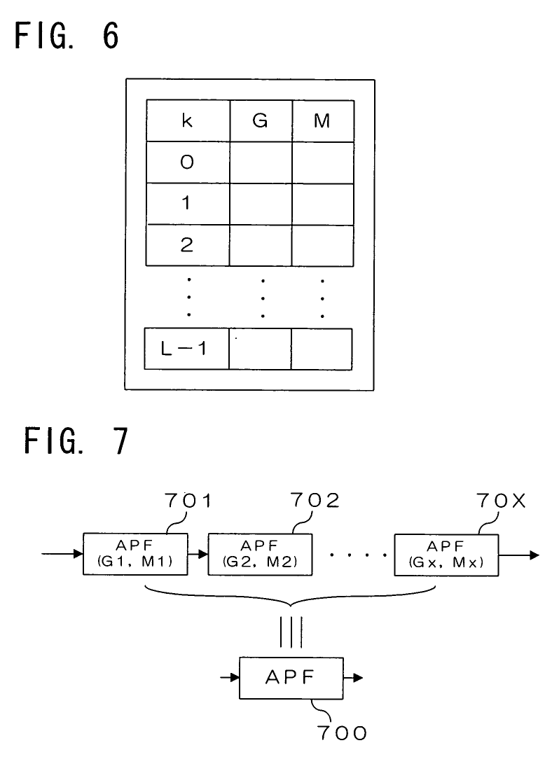

Now, the coefficient table will be discussed, with reference to FIG. 6. FIG. 6 schematically shows a coefficient table. The coefficient table is a table in which a set of the delay amount “M” and the gain “G” as an example of the “coefficient pair” according to the present invention is defined relative to the variant “k” as the index. The variant “k” is a value designing the size of the coefficient table, taking a value from “0” to “L−1” (L is natural number) in this embodiment. Therefore, L sets of the delay amount “M” and the gain “G” are prepared in advance for one coefficient table. The value “L” is determined in advance experimentally, empirically, or through a simulation, depending on the size of the sound field.

Again in FIG. 5, the CPU 210 sets the variant “k” to “0” (step S603). Then, the CPU 210 reads the coefficients corresponding to the variant “k” from the coefficient table, and stores them into the RAM 230 (step S604). Then, the CPU 210 sets the APF 320i on the basis of the coefficients stored into the RAM 230 (step S605). After the completion of the above processings, the BPF 310i and the APF 320i become acting as filters respectively.

Then, the CPU 210 controls the test signal generating device 240 to supply the test signal as an example of the “reference signal” according to the present invention to the BPF 310i (step S606). The test signal herein shall be an impulse signal. The signal component in the frequency band “i” is extracted from the test signal passing through the BPF 310i and supplied to the APF 320i. At the APF 320i, the infinite impulse response is performed as shown in FIG. 3, to generate the reflection sound pattern. The test signal in the frequency range “i” to which the reflection sound pattern is added is an example of the “corrected sound signal” according to the present invention, and outputted to the reproduction sound field from the speaker 10.

The test signal outputted from the speaker 10 through the BPF 310i and the APF 320i is collected by the microphone 250. The CPU 210 calculates the reverberation characteristic in the reproduction sound field, on the basis of the impulse response obtained from the collected signal (step S607).

Incidentally, the test signal generated by the test signal generating device 240 may be a maximum length sequence noise, a time stretched pulse and so on, instead of or in addition to the impulse signal. Furthermore, the form of the test signal is not limited to the examples described above, insofar as the signal from which the reverberation characteristic can be calculated by means of collected signals is within the “test signal” and this concept is guaranteed.

Furthermore, the calculation of the reverberation characteristic is not limited to the impulse response described above. For example, a random noise may be used as the test signal, to obtain the reverberation characteristic from this random noise. In this case, the damping process starting from a time point when the random noise stops outputted from the speaker 10 is measured by the microphone 250, and this measurement is repeated to obtain the reverberation characteristic as a mean or the like of measurements.

Once the reverberation characteristic of the reproduction sound field is calculated, the CPU 210 compares the reverberation characteristic “R0i” of the original sound field corresponding to the frequency band “i” already read into the RAM 230, with the calculated reverberation characteristic of the reproduction sound field, so that the error “Ek” is calculated (step S608). The calculated error “Ek” is temporarily stored into the RAM 230. Incidentally, the CPU 210 calculates the reverberation characteristic of the reproduction sound field in a form suitable for the comparison with the reverberation characteristic R0i of the original sound field. Insofar as this comparison is possible, the reverberation characteristic of the original sound field stored into the ROM 220 and the reverberation characteristic of the reproduction sound field stored into the RAM 230 may take any form.

Once the error “Ek” of the reverberation characteristic corresponding to the variant “k” (presently “0”) is stored into the RAM 230, the CPU 210 increments the variant “k” by “1” (step S609). Then, the CPU 210 judges whether or not the present value of the variant “k” equals to “L−1” (step S610). That is, the step S610 is a processing to check whether or not the error “Ek” is calculated for all coefficients prepared for the coefficient table.

If the calculation of the error “Ek” is not completed for all the coefficients (step S610: No), the CPU 210 makes the process return to step S604, to repeat processings from step S604 to S610.

Finally, if the calculation of the reverberation characteristic error “Ek” is completed for all the coefficients prepared for the coefficient table (step S610: Yes), the CPU 210 selects the minimum value from the plurality of“Ek”, whose number is L, temporarily stored in the RAM 230, i.e. the value providing the reverberation characteristic most analogous to the original sound field, so that the coefficients providing that “Ek”, i.e. the delay amount “M” and the gain “G” providing that “Ek” are stored into the RAM 230, as the coefficients of APF 320i corresponding to the frequency band “i” (step S611). Once the coefficients of APF 320i corresponding to the frequency band “i” are stored into the RAM 230, the calculation of the coefficients is terminated and the process goes back to the sound field control processing.

Incidentally, in this embodiment, the impulse signal is generated every time when the coefficients corresponding to the variant “k” is set to APF 320i, and collected by the microphone 250. In the large size of the coefficient table, however, such a generation for every setting of the coefficients may increase the processing load of the CPU 210. In such a case, the CPU 210 may measure the impulse response between the speaker 10 and the microphone 250, for every frequency band “i”, i.e. one time for one calculation of the coefficients of the APF 320i and store them into the RAM 230. On the basis of the impulse response stored as such, the CPU 210 may calculate the reverberation characteristic of the reproduction sound field when the coefficients are changed corresponding to the variant “k”, through a simulation or the like without an actual measurement.

Again in FIG. 4, once the coefficient calculation of APF 320i corresponding to the frequency band “i” ends, the CPU 210 increments the counter value “i” by “1” (step S503). Then, the CPU 210 judged whether or not the counter value “i” is “N” (step S504). That is, the step S504 is a process to check whether or not the coefficients of APF 320 are determined for all frequency bands. If there is any APF 320 whose coefficients are not determined (step S504: No), the CPU 210 makes the process return to step S502, to repeat the processes from step S502 to step S504 until the coefficients of APF 320 are determined for all frequency bands. Once the coefficients of APF 320 are determined for all frequency bands (step S504: Yes), the sound field control processing is terminated.

On the sound field control processing is completed, the sound field controlling system 100 can realize the reverberation characteristic analogous to the reverberation characteristic of the original sound field for all frequency bands in total N zones. The sound signal supplied to the signal processing unit 300 with this status is corrected by the signal processing unit 300 to the signal having the reverberation characteristic analogous to that of the original sound field, and synthesized by the synthesizing unit 330, and then supplied to the speaker 10 to be outputted to the reproduction sound field.

As discussed above, according to the sound field control system 100 of this embodiment, it is possible to obtain the reverberation characteristic of the reproduction sound field analogous to that of the original sound field only by determining two filter coefficients, i.e. the delay amount “M” and the gain “G”. Therefore, it is possible to shorten time required for the sound field control processing, and reduce the processing load of the CPU 210. Furthermore, since the APF 320 does not have the frequency dependency, the sound field control system 100 can realize the good frequency property without the frequency distortion. Furthermore, BPF 310, which divides the sound signal into each frequency band, divides the frequency band so as to include a part of the adjacent frequency bands, and thereby the reverberation characteristic is prevented from being discrete from a frequency band to adjacent frequency band, so that very natural reverberation characteristic is obtained.

Incidentally, the coefficient calculation above described is an example of the sound field control method according to the present invention. For example, the delay amount “M” may be determined prior to the gain “G”, when the coefficients of APF 320 are determined. The delay amount “M” means that the input signal is delayed for M sample minutes in the discrete time system. That is, the delay amount “M” is a parameter to define an addition period of the to-be-added reflection sound information, and a parameter relating to a spatial extent of the room of the reproduction sound field. On the other hand, the larger the gain “G”, the longer the damping time. Therefore, the gain “G” can be considered as a parameter to define the sound absorption coefficient of a wall surface in the reproduction sound field. Therefore, determining firstly the delay amount “M” equals to determining the spatial extent of the reproduction sound field. Thus, adjusting the gain “G” after approximating the reproduction sound field roughly to the original sound field makes it possible to shorten the time required for the sound field control processing. Incidentally, in the case that the delay amount “M” is firstly determined as mentioned above, the coefficient table is preferably in a form suitable to this.

Incidentally, for example, at a sample point where the reverberation characteristic of the reproduction sound field has a higher sound pressure level, as a result of the comparison of the reverberation characteristic of the reproduction sound field with the reverberation characteristic of the original sound field, the CPU 210 may control the signal processing unit 300 so as not to generate the reflection sound pattern. Diminishing the sound by the reflection sound having the reverse property has an effect only for a limited space of the reproduction sound field, and often makes unnaturalness acoustically. According to the control way of the present invention, however, this unnaturalness is prevented from arising.

Incidentally, in the case that the plurality of the delay amount “M” for all the frequency bands is the same, the CPU 210 may perform the coefficient calculation so as to change a part of the plurality of the delay amount “M”. In the case that the plurality of the delay amount “M” for all frequency bands is the same, a period for adding the reflection sound pattern is the same for all the frequency bands, and thus the periodicity of the reflection sound pattern is emphasized. In this case, it tends to be sensed by the audiences as the artificial reverberation sound. Therefore, it is possible to realize the natural reverberation characteristic in the reproduction sound field, by intensively controlling the delay amount “M” so as not to be even or uniform.

In the embodiment of the sound field control system according to the present invention, the construction of APF is not limited to that of the first embodiment. For example, the constructions as the second and third embodiments, which are described below, are applicable. Incidentally, in the second and third embodiments discussed below, the construction of the sound field control system is basically the same as the FIG. 1, but the construction of APFs in the signal processing unit 330.

### Second Embodiment

An explanation is made on the second embodiment of the APF according to the present invention, with reference to FIG. 7. FIG. 7 shows APFs 700 in a block diagram.

In FIG. 7, APFs 700 consists of APF 701 having coefficients “M1” and “G1”, APF 702 having coefficients “M2” and “G2”, . . . , and APF 70X having coefficient “Mx” and “Gx”. An output of a precedent APF is connected to an input of the following APF. The construction of each APF is almost the same as the construction of APF 320 in the first embodiment shown in FIG. 2.

During the operation of APFs 700 having such a construction, the reflection sound pattern as shown in FIG. 3 is added to each APF in the APFs 700, and the reflection sound pattern density becomes higher as the stage of the connected APF is higher. Therefore, it is possible to control the sound field in detail, and realize a more natural reverberation characteristic in the reproduction sound field.

### Third Embodiment

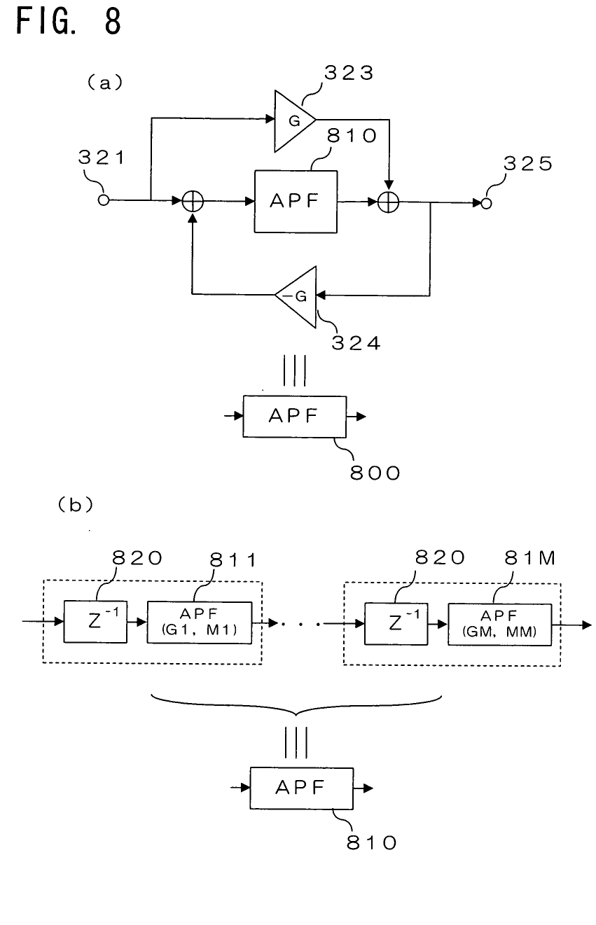

An explanation is made on the third embodiment of the sound field system according to the present invention, with reference to FIG. 8. FIG. 8 shows APFs 800 in a block diagram. Incidentally, in FIG. 8, parts or portions overlapped with FIG. 2 carry the same numerals, and the explanation of them is omitted.

In FIG. 8(a), APFs 800 has an APF 810 as a delay circuit. That is, the delay circuit 322 in FIG. 2 is replaced by the APF 810. In FIG. 8(b) shows an internal structure of APFs 810 in a block diagram. In APFs 810, a total M in number of a primary delay circuit 820 as an example of the “second delay device” according to the present invention, APF 811, APF 812, . . . , and APF 81M are subsequently connected. Incidentally, the “primary delay circuit” is a delay circuit whose delay amount is “1”.

In such a structure, an input signal to be inputted to APFs 800 is controlled by APFs 810 so as to have the delay amount “M”, and a signal phase is changed by each APF consisting APFs 810. Therefore, for example, in the case that all the delay amount is “M” for all frequency bands, the audio unnaturalness is alleviated, and the natural reverberation characteristic can be obtained.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

The entire disclosure of Japanese Patent Application No. 2004-20959 filed on Jan. 29, 2004 including the specification, claims, drawings and summary is incorporated herein by reference in its entirety.

1. A sound field control system for controlling a reverberation characteristic of a second sound field, on the basis of the measurement result of a reverberation characteristic of a first sound field which is measured in advance for a plurality of frequency bands, said sound field control system comprising:
a frequency dividing device for dividing a sound signal into the plurality of frequency bands;
a reverberation characteristic obtaining device for obtaining the reverberation characteristic of the second sound field for the plurality of frequency bands;
a detecting device for detecting a difference between the reverberation characteristic of the second sound field and the reverberation characteristic of the first sound field, for the plurality of frequency bands;
an infinite impulse response type filter for generating reflection sound information to be added to the sound signal divided into the plurality of frequency bands on the basis of the detected difference, for the plurality of frequency bands, and correcting the sound signal by adding the generated reflection sound information to the sound signal; and
a synthesizing device for synthesizing the corrected sound signal for the plurality of frequency bands.

2. The sound field control system according to claim 1, wherein
said infinite impulse response type filter includes a first delay device with a variable delay amount and a gain device with a variable gain, and
generates the reflection sound information on the basis of the delay amount and the gain.

3. The sound field control system according to claim 2, further comprising:
a coefficient holding device for holding a plurality of coefficient pairs in advance, each pair comprising the delay amount and the corresponding gain.

4. The sound field control system according to claim 3, wherein
said infinite impulse response type filter selects any one pair from among the coefficient pairs held by said coefficient holding device on the basis of the reverberation characteristic difference, and generates the reflection sound information on the basis of the delay amount and the gain corresponding to the selected coefficient pair.

5. The sound field control system according to claim 1, wherein
said infinite impulse response type filter is an all pass type filter.

6. The sound field control system according to claim 1, wherein
said frequency dividing device divides the sound signal so that each of the divided frequency bands has a common zone with an adjacent zone.

7. The sound field control system according to claim 1, wherein
said reverberation obtaining device includes: a reference signal generating device for generating a reference signal; and a sound collecting device for collecting the reference signal outputted as a sound wave to the second sound field after through said frequency dividing device and said infinite impulse response type filter, in the second sound field, and
obtains the reverberation characteristic of the second sound field on the basis of the collected reference signal.

8. The sound field control system according to claim 1, wherein
said infinite impulse response type filter is made of a plurality of the infinite impulse response type filters, which are subsequently connected.

9. The sound field control system according to claim 2, wherein
the first delay device is the infinite impulse response type filter.

10. The sound field control system according to claim 9, wherein
said infinite impulse response type filter includes: a second delay device having a fixed delay amount; and the infinite impulse response type filter.

11. A sound field control method of controlling a reverberation characteristic of a second sound field, on the basis of the measurement result of a reverberation characteristic of a first sound field which is measured in advance for a plurality of frequency bands, and, said sound field control method comprising:
a frequency dividing process of dividing a sound signal into the plurality of frequency bands;
a reverberation characteristic obtaining process of obtaining the reverberation characteristic of the second sound field for the plurality of frequency bands;
a detecting process of detecting a difference between the reverberation characteristic of the second sound field and the reverberation characteristic of the first sound field, for the plurality of frequency bands;
a sound signal correcting process of generating reflection sound information to be added to the sound signal divided into the plurality of frequency bands on the basis of the detected difference, and correcting the sound signal by adding the generated reflection sound information to the sound signal, by an infinite impulse response type filter; and
a synthesizing process of synthesizing the corrected sound signal for the plurality of frequency bands.

12. The sound field control method according to claim 11, wherein
the infinite impulse response type filter includes a delay device with a variable delay amount and a gain device with a variable gain, and
said sound signal correcting process includes a process of determining the delay amount and the gain on the basis of the detected reverberation difference.

13. The sound field control method according to claim 12, wherein
the gain is determined after the delay amount is determined at said sound signal correcting process.

14. The sound field control method according to claim 12, wherein
the delay amount is adjusted to be different at least partially for the plurality of frequency bands, at said sound signal correcting process.

15. The sound field control method according to claim 11, wherein said reverberation characteristic obtaining process includes:
a process of outputting a reference signal as a sound wave by an outputting device in the second sound field; and
a process of collecting the outputted reference signal by a sound collecting device,
the reverberation characteristic is obtained on the basis of the collected reference signal.

16. The sound field control method according to claim 15, wherein
the reference signal is an impulse signal,
the reverberation characteristic is obtained on the basis of an impulse response between the outputting device and the sound collecting device.

17. The sound field control method according to claim 16, wherein
said reverberation characteristic obtaining process includes a process of obtaining the reverberation characteristic through a simulation based on the impulse response.

18. The sound field control method according to claim 15, wherein
the reference signal is a random noise signal,
the reverberation characteristic is obtained on the basis of the random noise collected over a plurality of times.
